(19) United States
(12) Patent Application Publication
(10) Pub. No.: US 2021/0377652 A1
(43) Pub. Date: Dec. 2, 2021

(54) MEMS ULTRASONIC TRANSDUCER

(71) Applicant: Knowles Electronics, LLC, Itasca, IL (US)

(72) Inventors: Andrew UNRUH, San Jose, CA (US); Martin VOLK, Willowbrook, IL (US)

(73) Assignee: Knowles Electronics, LLC, Itasca, IL (US)

(21) Appl. No.: 16/322,463

(22) PCT Filed: Jul. 28, 2017
(86) PCT No.: PCT/US17/44471

§ 371 Date: Jan. 31, 2019

Related U.S. Application Data
(60) Provisional application No. 62/370,160, filed on Aug. 2, 2016.

(51) Int. Cl. H04R 1/30; G10K 11/28; B81B 3/00; G10K 9/22

(52) U.S. Cl. CPC H04R 1/30; G10K 11/28; B81B 3/0064; B81B 2201/0257; G10K 9/22; H04R 2201/003; B81B 3/0021

(57) ABSTRACT

An ultrasonic device includes a substrate, a transmitter disposed over the substrate, the transmitter including an ultrasonic transmitting transducer configured to generate ultrasonic signals, and a receiver disposed over the substrate, the receiver including an ultrasonic receiving transducer configured to sense ultrasonic signals. The ultrasonic device further includes a first horn-shaped acoustic channel, wherein a material of at least one portion of the first horn-shaped acoustic channel is the same as a material of at least one portion of the transmitter or the receiver.

### CROSS-REFERENCE TO RELATED APPLICATIONS

This application claims the benefit of and priority to U.S. Provisional Patent Application No. 62/370,160, filed Aug. 2, 2016, the entire contents of which are incorporated herein by reference.

### BACKGROUND

The present disclosure is in the field of transducers, and specifically to improvements to range or efficiency of transducers.

Although various types of transducers are available, range and efficiency continue to be challenges faced in transducer design.

### SUMMARY

In an embodiment, an ultrasonic device includes a substrate, a transmitter disposed over the substrate, the transmitter including an ultrasonic transmitting transducer configured to generate ultrasonic signals, and a receiver disposed over the substrate, the receiver including an ultrasonic receiving transducer configured to sense ultrasonic signals. The ultrasonic device further includes a first horn-shaped acoustic channel, wherein a material of at least one portion of the first horn-shaped acoustic channel is the same as a material of at least one portion of the transmitter or the receiver.

In an embodiment, an ultrasonic device includes a substrate, a transmitter disposed over the substrate including an ultrasonic transmitting transducer configured to generate ultrasonic signals, and a receiver disposed over the substrate including an ultrasonic receiving transducer configured to sense ultrasonic signals. The ultrasonic device further includes a first housing disposed over the substrate defining a first cavity, the first cavity including the transmitter and the receiver, and a surface of the first housing defines a first aperture. The ultrasonic device further includes an acoustic channel having a first opening and an opposing second opening, the first opening coupled to the first aperture and the second opening coupled to the cavity, and a length of the acoustic channel is substantially equal to one half of an operating wavelength of the transmitter or the receiver.

In an embodiment, an ultrasonic device includes a substrate having a first planar surface and a second opposing planar surface, a transmitter disposed over the first planar surface of the substrate, and a receiver disposed over the first planar surface of the substrate. The ultrasonic device further includes a first horn-shaped acoustic channel defined by the substrate, the first horn-shaped acoustic channel extending from a first opening defined in the first planar surface to a second opening defined in the second planar surface, wherein the first opening is proximate to the transmitting transducer. The ultrasonic device further includes a second horn-shaped acoustic channel defined by the substrate, the second horn-shaped acoustic channel extending from a third opening defined in the first planar surface to a fourth opening defined in the second planar surface, wherein the third opening is proximate to the receiving transducer.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 is a representation of an example of an ultrasonic transducer in accordance with various implementations.

FIG. 2A is a representation of an example of an ultrasonic transducer incorporating top port horns in accordance with various implementations.

FIG. 2B depicts a top view of a portion of FIG. 2A in accordance with various implementations.

FIG. 2C depicts a top view of a portion of FIG. 2A in accordance with various implementations.

FIG. 2D depicts a top view of a portion of FIG. 2A in accordance with various implementations.

FIG. 3 shows an example of an intermediate stage in a manufacture process for a MEMS transmitter in accordance with various implementations.

FIG. 4 is a representation of an example of an ultrasonic transducer incorporating bottom port horns in accordance with various implementations.

FIG. 5 is a representation of an example of an ultrasonic transducer including a tuned port in accordance with various implementations.

FIG. 6 is a representation of an example of an ultrasonic transducer including a horn-shaped tuning port in accordance with various implementations.

FIG. 7 is a representation of an example of an ultrasonic transducer including a horn-shaped tuning port and an ultrasonic transceiver in accordance with various implementations.

FIG. 8 is a representation of an example of an ultrasonic transducer incorporating bottom port horns and an ultrasonic transceiver in accordance with various implementations.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

### DETAILED DESCRIPTION

The present disclosure describes devices and techniques to improve a range and an efficiency of ultrasonic transducers. In one or more embodiments, range and efficiency of ultrasonic proximity sensors incorporating microelectromechanical systems (MEMS) transducers are improved.

In one or more embodiments, a MEMS microphone is used as a transducer. A MEMS microphone may include, for example, a MEMS die with one or more diaphragm and one or more back plate. The MEMS die may be supported by a base or substrate and enclosed by a housing (e.g., a cupped cover or cover with walls). A port may extend through the substrate (for a bottom port device) or through the top of the housing (for a top port device). Sound energy traverses through the port, moves the diaphragm, and creates a changing electrical potential of the back plate, which creates an electrical signal.

In one or more embodiments, a proximity sensor may include a piezoelectric device. A piezoelectric device may be constructed with such materials that bending or application of stress to the piezoelectric device generates electrical energy.

In one or more embodiments, horns are incorporated into one of, or both, a transmitter and a receiver of a proximity sensor.

In one or more embodiments, a bandpass enclosure is incorporated to house a transmitter and a receiver of a proximity sensor.

In one or more embodiments, horns and a bandpass enclosure are incorporated into a proximity sensor.

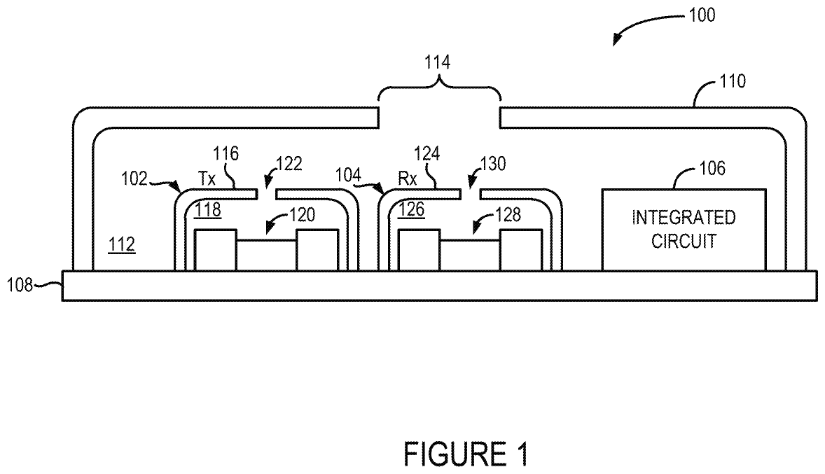

FIG. 1 is a representation of an example of an ultrasonic transducer 100 according to embodiments of the present disclosure. The ultrasonic transducer 100 includes an ultrasonic transmitter 102 (“transmitter 102”), an ultrasonic receiver 104 (“receiver 104”), and an integrated circuit (IC) 106. IC 106 may be, in one or more embodiments, an application specific IC (ASIC). The transmitter 102, the receiver 104 and the IC 106 are disposed on a substrate 108. The substrate 108 may be, for example, a semiconductor substrate or a printed circuit board. While not shown in FIG. 1, in one or more embodiments, the substrate 108 can provide connectivity, by way of interconnects, vias, or traces, between the transmitter 102, the receiver 104 and the IC 106. In some other embodiments, connectivity can be provided additionally or alternatively by way of bonding wires.

The ultrasonic transducer 100 also includes a transducer housing 110 that defines a first cavity 112 and encompasses the transmitter 102, the receiver 104, and the IC 106. The transducer housing 110 also defines a first opening 114 over its surface to allow for sound generated by the transmitter 102 to exit the transducer housing 110, and to allow sound to enter the cavity 112. For example, sound generated by the transmitter 102 and exited through the first opening 114 may be reflected by objects near the first opening 114 and may re-enter the first cavity 112 through the first opening 114 and be potentially sensed by the receiver 104.

The transmitter 102 includes a transmitter housing 116 that defines a second cavity 118 and encompasses a transmitting transducer 120. The transmitter housing 116 also defines an aperture on one of its sides, where the aperture serves as a transmitter port 122 to allow for ultrasonic sound generated by the transmitting transducer 120 to exit the transmitter housing 116. In one or more embodiments, the aperture can be formed on a different surface of the transmitter housing 116 than the one shown in FIG. 1. In one or more embodiments, the transmitter housing 116 can define more than one aperture. Receiver 104 includes a receiver housing 124 that defines a third cavity 126 and encompasses a receiving transducer 128. The receiver housing 124 also defines an aperture on one of its sides, where the aperture serves as a receiver port 130 to allow for ultrasonic sounds to enter the receiver housing 124 and be sensed by the receiving transducer 128. In one or more embodiments, the aperture can be formed on a different surface of the receiver housing 124 than the one shown in FIG. 1. In one or more embodiments, the receiver housing 124 can define more than one aperture.

In embodiments such as illustrated in FIG. 1, the transmitter 102 and the receiver 104 are implemented using different devices. The transmitter 102 can be implemented using, for example, a piezoelectric device, a microphone driven as a speaker, a speaker, or other transmitting device. The receiver 104 can be implemented using, for example, a microphone, a speaker operated in reverse, or other receiving device.

In one or more embodiments, both the transmitter 102 and the receiver 104 are implemented within a single device. For example, a MEMS microphone can be utilized to implement both the transmitting transducer 120 and the receiving transducer 128. In such embodiments, the MEMS microphone may be operated as a transmitter of ultrasonic sound waves for a first duration, during which it can operate as a speaker. That is, the MEMS microphone, during the first duration, can convert electrical signals into ultrasonic sound. The MEMS microphone can also be operated as a receiver for a second duration, during which it may be operated as a microphone. That is, the MEMS microphone can receive ultrasonic sound during the second duration and convert the received ultrasonic sound into electrical signals. The first and second durations can be interspaced over time to allow the MEMS microphone to alternate between transmitting and receiving ultrasonic sound. A controller, such as the IC 106, can be configured to control the mode of the MEMS microphone (e.g., control when the MEMS microphone switches between operation as a transmitter and operation as a receiver).

The transmitter 102 transmits ultrasonic signals, such as sound signals having frequencies above the human audible range (e.g., above about 20 kHz). For example, the ultrasonic signals transmitted by the transmitter 102 can be in a range of about 20 kHz to about 200 kHz. Although the embodiments described herein discuss the transmitter 102 and the receiver 104 as operating in the ultrasonic frequency range, in one or more embodiments, the transmitter 102 and the receiver 104 also can operate in other frequency bands. For example, in one or more embodiments, the transmitter 102 is configured to transmit sound signals that overlap both an audible range of frequencies and an ultrasonic range of frequencies. For example, the transmitter 102 can be used in a telephone (e.g., a mobile phone) as a speaker, which not only transmits voice signals generated by the telephone, but also transmits ultrasonic signals that are utilized to determine a proximity of a user to the telephone. In one or more embodiments, the receiver 104 is configured to receive sound in an ultrasonic frequency range. In other embodiments, the receiver 104 is configured to receive sound in both audible frequency ranges and ultrasonic frequency ranges. For example, the receiver 104 can be utilized in a telephone to sense sounds emitted by the user (e.g., the user's voice), and also to sense ultrasonic sound signals transmitted by an ultrasonic transmitter to detect the proximity of the user to the telephone.

As mentioned above, the IC 106 can be electrically connected to the transmitter 102 and the receiver 104. The IC 106 can include various analog and digital components for controlling the transmitter 102 and the receiver 104 and to process signals to the transmitter 102 and from the receiver 104. For example, the IC 106 can include processing circuitry for generating data signals to be transmitted by the transmitter 102 and for processing signals received from the receiver 104. To that end, the processor may also include digital-to-analog converters (DACs) and analog to digital converters (ADCs) for converting signals between the analog and digital domain. The processor can also be coupled to analog components such as amplifiers, oscillators, transistors, resistors, capacitors, inductors, power supplies, transformers, and so forth that can aid in the operation of the processor.

As mentioned above, the ultrasonic transducer 100 shown in FIG. 1 can be utilized, for example, as a proximity sensor. In one or more embodiments, a range over which the ultrasonic transducer 100 can detect a proximity of objects can be a function of a strength of the ultrasound signal transmitted by the transmitter 102 and/or a sensitivity of the receiver 104. In one or more such embodiments, providing additional power to the transmitter 102 and/or the receiver 104 can improve the strength and/or sensitivity, respectively, thereby improving the range of proximity detection of the ultrasonic transducer 100. However, in one or more embodiments, such as low power applications, the increase in power to improve range may not be feasible or desirable. The following discussion provides example approaches for improving the range and sensitivity of the ultrasonic transducer 100 without an increase in power consumption.

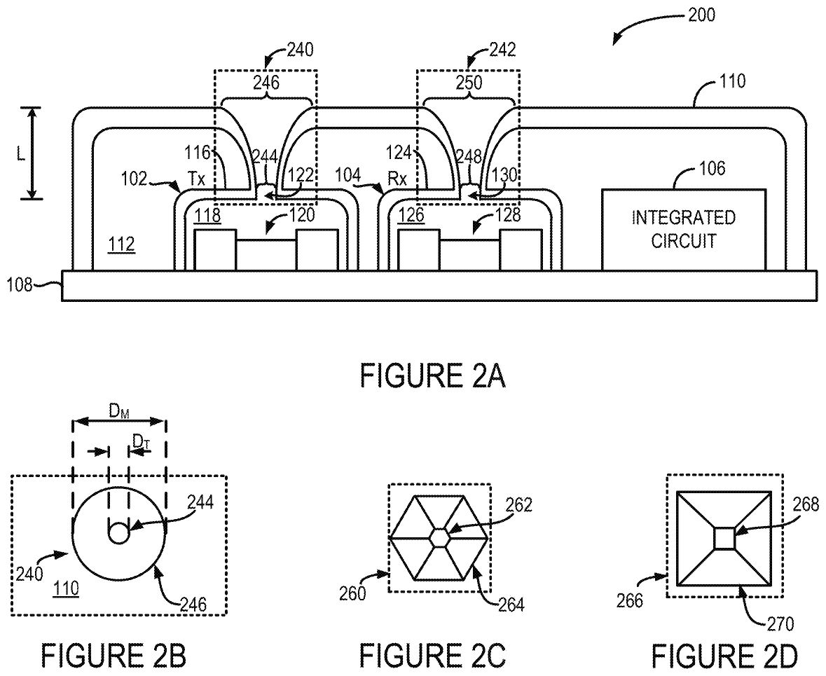

FIG. 2A illustrates an embodiment of an ultrasonic transducer 200 incorporating horns for improved range and sensitivity. In particular, the ultrasonic transducer 200 includes a transmitter horn 240 and a receiver horn 242. The transmitter horn 240 is coupled to the transmitter 102 and the receiver horn 242 is coupled to the receiver 104. Specifically, a throat (narrow end) 244 of the transmitter horn 240 is coupled to, or forms, the port 122 in the transmitter housing 116, while a mouth (broad end) 246 of the transmitter horn 240 is coupled to the transducer housing 110. Similarly, a throat 248 of the receiver horn 242 is coupled to, or forms, the port 130 in the receiver housing 124, while a mouth 250 of the receiver horn 242 is coupled to the transducer housing 110. Each of the transmitter horn 240 and the receiver horn 242 forms a channel that extends from its respective transducer to outside of the transducer housing 110.

The transmitter horn 240 and the receiver horn 242 can improve efficiency and directionality of the transmitter 102 and the receiver 104. In one or more embodiments, the transmitter horn 240 can increase a load experienced by the transmitting transducer 120, thereby improving its efficiency. In one or more embodiments, the receiver horn 242 can strengthen a sound energy incident on the receiving transducer 128, thereby improving its sensitivity. In addition, the transmitter horn 240 and the receiver horn 242 improve the directionality of the transmitter 102 and the receiver 104, respectively. In one or more embodiments, one of, or both of, the transmitter horn 240 and the receiver horn 242 are configured to provide a coverage angle of about 45° to about 135° centered around a longitudinal axis of the respective horn.

FIG. 2B depicts a top view of a portion of the transducer housing 110 shown in FIG. 2A illustrating an embodiment of the transmitter horn 240. In particular, FIG. 2B shows the transmitter horn 240 having a substantially circular cross-section at the mouth 246 and at the throat 244. The mouth 246 and the throat 244 have diameters D_{M} and D_{T}, respectively. Referring to FIG. 2A, the transmitter horn 240 has a length L, which extends from the throat 244 to the mouth 246. Generally, the cross-sectional area of the transmitter horn 240 in a plane substantially normal to the longitudinal axis of the horn increases along the length L of the horn from the throat 244 to the mouth 246. In one or more embodiments, the transmitter horn 240 can have a substantially exponential shape (an exponentially-increasing cross-sectional area of the horn from the throat 244 to the mouth 246. The shape of the transmitter horn 240 is not limited to an exponential shape. In one or more embodiments, the transmitter horn 240 can have a shape that is substantially parabolic, linear, hyperbolic, conic, or other shape. The receiver horn 242 may have a same shape as the transmitter horn 240. Alternatively, the receiver horn 242 may have a different shape than the transmitter horn 240. Further, when the transmitter horn 240 and the receiver horn 242 have a similar shape, dimensions of the transmitter horn 240 may be substantially the same as, or may be different than, dimensions of the receiver horn 242.

FIGS. 2C and 2D each depict top views of a portion of the transducer housing 110 shown in FIG. 2A illustrating additional horn shape examples for implementing the transmitter horn 240 and/or the receiver horn 242. In particular, FIG. 2C depicts in top view a horn 260 that has a throat 262 and a mouth 264 with hexagonal shapes, while FIG. 2D depicts in top view a horn 266 that has a throat 268 and a mouth 270 with rectangular shapes. It is to be understood that horns with other shapes, such as elliptical, square, irregular, and so forth also can be utilized.

The shape and dimensions of the transmitter horn 240 and the receiver horn 242 can impact acoustic responses of the horns. In particular, the shape and dimensions of the transmitter horn 240 (e.g., D_{T}, D_{M}, and L, shown in FIGS. 2A and 2B) and the receiver horn 242 can be configured such that their acoustic responses matches desired operational frequencies of the transmitter 102 and the receiver 104, respectively. For example, in one or more embodiments of the transmitter horn 240 illustrated in FIGS. 2A and 2B, the diameter D_{M} of the mouth 246 and the length L of the transmitter horn 240 can be made substantially equal to ¼ times the wavelength and ½ times the wavelength, respectively, of the sound generated by the transmitter 102. Based on the determined diameter D_{M} and the length L, given a selected design shape of the horn (and assuming that the shape is implemented as designed), the diameter D_{T} of the throat of the horn can be derived.

In one or more other embodiments, in which an exponentially shaped transmitter horn 240 with the throat 244 and the mouth 246 having circular cross-sections is utilized, for a given operating frequency f_{c}, an area of the cross section of the mouth 246 can be approximated by the following Equation (1):

$${A}_{M} = \frac{{( \frac{c}{2 {f}_{c}} )}^{2}}{π} \qquad ( 1 )$$

where c is the speed of sound. Further, a relationship between the frequency f_{c}, the cross sectional area A_{T} of the throat 244, and the length L can be approximated by the following Equation (2):

$${f}_{c} = \frac{c \cdot ln ( {A}_{M} / {A}_{T} )}{π \cdot L} \qquad ( 2 )$$

Thus, selecting one of the length L or the throat cross sectional area A_{T} the other of L and A_{T} can be determined. The above equations for determining the dimensions of the transmitter horn 240 also can be applied to determine the dimensions of the receiver horn 242, where the frequency f_{c} corresponds to a sensing frequency of the receiving transducer 128. It should be understood that the above discussed technique for determining the dimensions of the transmitter horn 240 and the receiver horn 242 is discussed by way of example, and that other techniques including different expressions relating the dimensions of the horns to the operational frequency can be utilized. In one or more embodiments, given the operational frequency, the dimensions of the horns also can be determined based on experimental techniques or by using acoustic simulation software.

In one or more embodiments, throats of the transmitter horn 240 and the receiver horn 242 can be attached to the transmitter housing 116 and the receiver housing 124, respectively, by a bonding agent, such as for example, glue, solder, or epoxy. In one or more such embodiments, the diameter of the ports 122 and 130 can be equal to the diameter D_{T} of the throats 244 and 248, respectively. The mouths of the transmitter horn 240 and the receiver horn 242 can be attached to the transducer housing 110 also by a bonding agent. For example, the transducer housing 110 can include apertures that can accommodate the shape and size of the mouths 246 and 250 of the transmitter horn 240 and the receiver horn 242, respectively. In one or more embodiments, the transmitter horn 240 and the receiver horn 242 can be formed of a material such as metal, plastic or resin, or a combination of metal, plastic or resin, or other material, the material providing sufficient wall strength to maintain the designed horn shape.

In some other embodiments, the transmitter horn 240 and the receiver horn 242 can be integrated respectively into the transmitter 102 and the receiver 104. In particular, instead of separately manufacturing horns and attaching the manufactured horns to the transmitter 102 and the receiver 104 as the transmitter horn 240 and the receiver horn 242, respectively, the transmitter horn 240 and the receiver horn 242 can be manufactured along with the respective transmitter 102 and receiver 104 (e.g., in a same manufacturing process stage). In one or more such implementations, the material(s) used for forming the transmitter horn 240 and the receiver horn 242 can be similar to material(s) used in forming other features of the transmitter 102 and receiver 104.

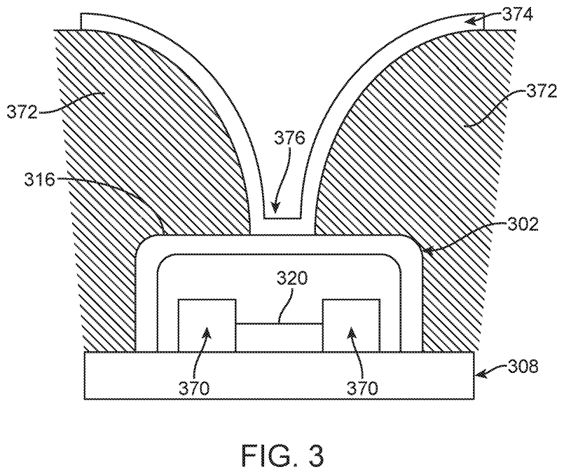

FIG. 3 illustrates an example of an intermediate process stage in the manufacture of a MEMS transmitter 302 manufactured using MEMS techniques. In particular, FIG. 3 shows an intermediate stage of manufacture of the MEMS transmitter 302 in which a transmitter horn is integrated with a transmitter housing 316. In FIG. 3, the transmitter 302 is disposed on a substrate 308. The transmitter 302 includes a transmitting transducer 320 supported by a support structure 370 and enclosed in the transmitter housing 316. A sacrificial layer 372 is deposited over the transmitter housing 316 and is patterned to form a mold that conforms to a shape and a size of a desired transmitter horn. In one or more embodiments, the sacrificial layer 372 can be formed by deposition of polymer materials, such as polyamide or fluoropolymer. The sacrificial layer 372 can be pattered using a photoresist or an etch mask, and etched using etching techniques such as chemical etching, isotropic etching, or anisotropic etching. Once the sacrificial layer 372 is patterned to form the mold, a horn layer 374 can be deposited over the patterned sacrificial layer 372. The horn layer 374 can include one or more materials utilized for forming the transmitter housing 316 or other component of the transmitter 302. For example, the material used for both the horn layer 374 and the transmitter housing 316 can include metals such as aluminum, copper, nickel, chromium, titanium, niobium, or alloys thereof; dielectric materials such as aluminum oxide, silicon oxide, tantalum pentoxide, or silicon nitride; or semiconductor materials such as silicon, germanium, or gallium arsenide. In one or more embodiments, the materials used for forming the horn layer can be similar to the materials used for forming the transmitting transducer 320. In one or more such embodiments, materials such as metals, dielectrics, and semiconductors mentioned above can be utilized. In one or more embodiments, the horn layer 374 can include multiple layers of metals, semiconductors, insulators, or other materials. In one or more such implementations, one or more sub-layers of the horn layer 374 can be utilized for carrying electrical signals, or for forming other electrical components of the acoustic sensor.

After the deposition of the horn layer 374, the horn layer can be patterned, such as by using photomasks and etching techniques. During patterning, a portion 376 of the horn layer 374 and the underlying portion of the transmitter housing 316 can be etched to form an auditory channel to the cavity formed by the transmitter housing 316, thereby forming a throat of a horn. The sacrificial layer 372 is then removed, thereby resulting in a horn such as the transmitter horn 240 shown in FIG. 2A. In one or more embodiments, a receiver horn (such as the receiver horn 242, FIG. 2A) integrated into a receiver (such as the receiver 104, FIG. 2A) can be formed in a manner similar to that discussed above for forming the transmitter horn (FIG. 3). In one or more such embodiments, the transmitter 302 and receiver along with the integrated horns can be attached or coupled to a transducer housing such as the transducer housing 110 in FIG. 2A. The transducer housing can include openings to accommodate the mouths of the integrated transmitter and receiver horns. Any gaps between the boundaries of the mouths of the horns and the transducer housing can be sealed to form an enclosed cavity for housing the transmitter 302 and the receiver.

By forming the horn structure during the MEMS fabrication of the transmitter and receiver, one can take advantage of the natural bonding provided by a MEMS deposition process. Thus, a horn structure (e.g., formed by the horn layer 374 in FIG. 3) may not need any bonding agents to bond the horn structure to the underlying transmitter or receiver housing. This can be advantageous, as the resultant horn structure, which is integrated into the transmitter structure, can have improved rigidity, thereby reducing unwanted vibrations. Furthermore, the risk of variations in the sizes of the throats associated with the use of bonding agents can be mitigated. For example, as the throats of the horn structure are formed using photo-patterning, their size and position can be precisely controlled. In contrasting approaches, horn structures can be attached to the transmitters and/or receivers after completion of a MEMS fabrication process used to fabricate the associated transmitters and receivers. For example, the horn structures can be attached to the transmitters and receivers during packaging of an acoustic transducer or when the acoustic transducer is mounted on a printed circuit board. In some such approaches, bonding agents such as glue, epoxy, solder or other bonding agent can be utilized to bond the throats of the horns to ports on the transmitter housing and the receiver housing. Faults in either the materials or the processes used for bonding may result in deficient bonding between the horns and their respective transducers. This, in turn, can result in loss in the rigidity of the combined horn and transducer structure. In some instances the lack of rigidity can result in undesired vibrations, which may lead to structural damage or detachment of the horns from the transducers. In some instances, imprecise deposition of the bonding agent or imprecise positioning of the horn structure in relation to the ports on the transmitter or the receiver can result in variations in the sizes of the openings at the throat of the horn structure, causing variations in the auditory response of the respective transducers. Thus, integration of the horn structures into the transmitter and receiver housings can provide for improvements in acoustic features of an ultrasonic transducer.

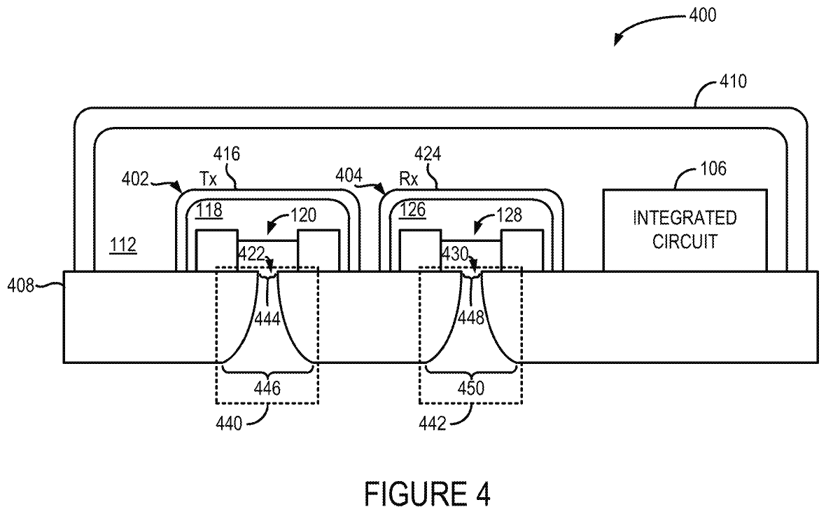

FIG. 4 illustrates an example of an embodiment of an ultrasonic transducer 400 incorporating horns in bottom ports. In particular, FIG. 4 shows an ultrasonic transducer 400 incorporating horns within a substrate 408 over which a transmitter 402 and a receiver 404 are disposed. The transmitter 402 and the receiver 404 are similar to the transmitter 102 and the receiver 104 shown in FIG. 2A, in that the transmitter 402 and the receiver 404 also include a transmitting transducer 120 and a receiving transducer 128, respectively. However, unlike the transmitter 102 and the receiver 104 shown in FIG. 2A, in which the transmitter horn 240 and the receiver horn 242 are respectively coupled to the front ports 122 and 130, the transmitter 402 and the receiver 404 shown in FIG. 4 respectively include a transmitter horn 440 and a receiver horn 442 coupled to respective bottom ports 422 and 430. Furthermore, the transmitter horn 440 and the receiver horn 442 are formed by horn-shaped channels within the substrate 408. The transmitter horn 440 includes a throat 444 and a mouth 446, where the throat 444 is coupled to the bottom port 422 of the transmitter 402. Similarly, the receiver horn 442 includes a mouth 450 and a throat 448 coupled to the bottom port 430 of the receiver 404.

In one or more embodiments, such as the one shown in FIG. 4, a transmitter housing 416, a receiver housing 424 and a transducer housing 410 do not include any openings. In one or more other embodiments, one or more of the above-mentioned housings can include ports. For example, the ports can be tuning ports that can be configured based on desired auditory responses of the ultrasonic transducer 400.

In one or more embodiments, the substrate 408 can be a printed circuit board over which the ultrasonic transducer 400 is mounted. In other embodiments, the substrate 408 can be a semiconductor die over which the ultrasonic transducer 400 is fabricated. In yet other embodiments, the substrate 408 can be a combination of a semiconductor die and a printed circuit board. One advantage of the ultrasonic transducer 400 with bottom port connected horns is that no additional material is needed to form the horns; instead, the existing substrate 408 can be utilized for forming the horns.

The dimensions and the shape of the transmitter horn 440 and the receiver horn 442 can be determined in a manner similar to that discussed above in relation to the transmitter horn 240 and the receiver horn 242 shown in FIG. 2A. Further, various configurations of the throat and mouth of the horns shown in FIGS. 2C and 2D can be utilized for forming the throat and mouths of the transmitter horn 440 and the receiver horn 442 shown in FIG. 4.

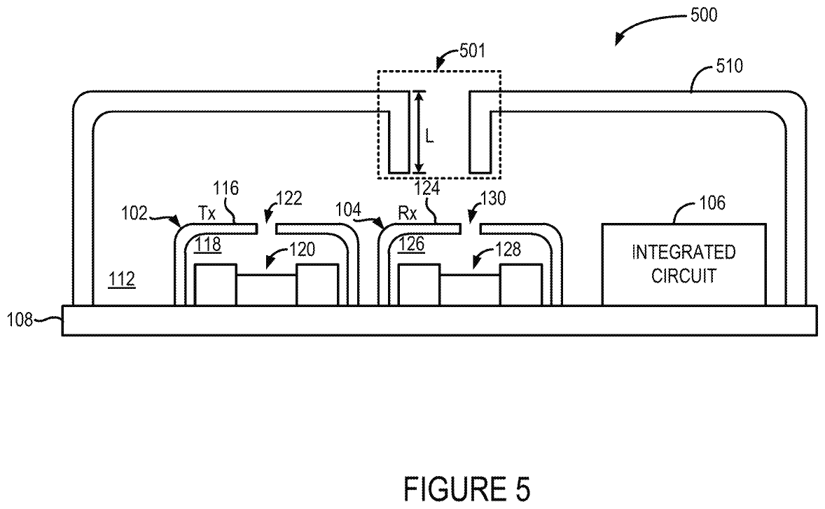

FIG. 5 illustrates an example of an embodiment of an ultrasonic transducer 500 including a tuned port 501. In particular, the ultrasonic transducer 500 includes the tuned port 501 formed in a transducer housing 510. The transducer housing 510 encompasses a transmitter 102, a receiver 104 and an IC 106 as described with respect to FIG. 1. The tuned port has a length L and a cross sectional area in a plane that is substantially normal to the longitudinal (along the length) axis of the tuned port 501. The tuned port 501 and the transducer housing 510 form a Helmholtz resonator, a resonance frequency of which is tuned to an operating frequency f_{c} of the transmitter 102 and/or the receiver 104. Generally, the tuned port 501 in combination with a first cavity 112 forms a bandpass enclosure a center frequency of which is a resonance frequency of the bandpass enclosure. For example, in one or more embodiments, a relationship between the operating frequency f_{c} and dimensions of the transducer housing 510 including the tuned port 501 can be expressed by the following Equation (3):

$${f}_{c} = \frac{c}{2 π} \sqrt{\frac{A}{{V}_{0} L}} \qquad ( 3 )$$

where c denotes the speed of sound, A denotes the cross-sectional area of the tuned port 501, L denotes a length of the tuned port 501, and V₀ denotes a static volume of the first cavity 112 formed by the transducer housing 510. In one or more embodiments, a size of the transducer housing 510, and hence the volume V₀, may be constrained by application size of a device in which the ultrasonic transducer 500 is deployed. Thus, given a volume V₀, the area A and the length L of the tuned port 501 can be selected such that the resonance frequency of the bandpass enclosure is substantially equal to an operating frequency of the ultrasonic transducer 500. By designing the resonance frequency of the bandpass enclosure to be substantially equal to the operating frequency of the ultrasonic transducer 500, the enclosure can amplify sound produced by the transmitter 102. Thus, an efficiency of the transmitter 102 can be improved and a sensitivity of the receiver 104 can be improved as well. It should be understood that the relationship between the resonant frequency of the bandpass enclosure and the dimensions of the enclosure as described above is presented by way of non-limiting example. A person skilled in the art can realize a different set of equations to determine the dimensions of the transducer housing 510 and the tuned port 501 to achieve a resonant frequency that is substantially equal to the operating frequency of the ultrasonic transducer 500. In one or more embodiments, the dimensions of the transducer housing 510 and the tuned port 501 can be determined experimentally or by using computer simulations. In one or more embodiments, the length L of the tuned port 501 can be selected to be about ½ the wavelength of the operating frequency of the ultrasonic transducer 500 to achieve resonance.

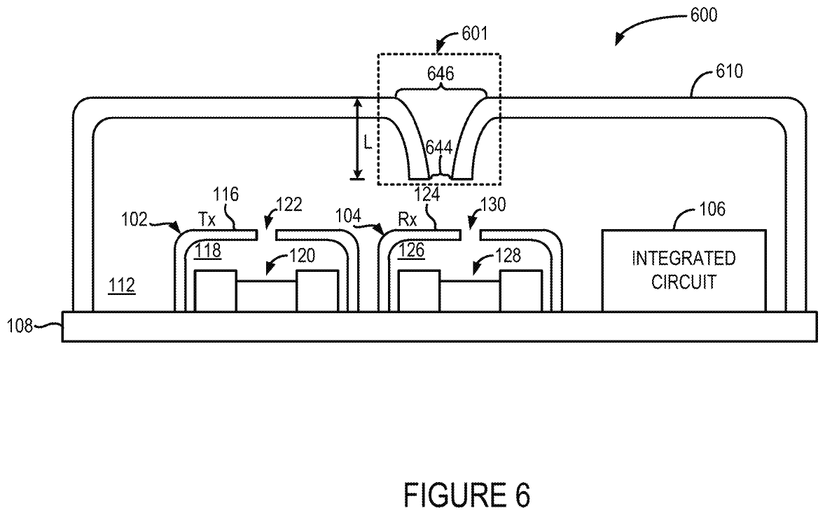

FIG. 6 illustrates an example of an embodiment of an ultrasonic transducer 600 which utilizes a horn-shaped tuning port 601. In particular, the ultrasonic transducer 600 includes a port that is similar to the tuned port 501 shown in FIG. 5. However, unlike the tuned port 501, which has a linear profile, the tuning port 601 has a horn shape, similar to the transmitter horn 240 and the receiver horn 242 discussed above in relation to FIG. 2A. The horn-shaped tuning port 601 includes a throat 644 and a mouth 646, which is coupled to a transducer housing 610. The horn-shaped tuning port 601 combines the advantages of both the tuned port 501 shown in FIG. 5 and the horns 240 and 242 shown in FIG. 2A. In particular, a length L of the horn-shaped turning port 601 can be selected such that a resonance frequency of the transducer housing 610 is substantially equal to an operating frequency f_{c} of the transmitter 102 and/or the receiver 104. For example, in one or more embodiments, the length L of the port 601 can be selected to be about ½ the wavelength of the operating frequency of the ultrasonic transducer 600. Further, the horn shape of the port 601 provides strengthening of the sound energy in and out of the transducer 600, thereby improving a range of the transducer 600. In addition, the horn shape of the port 601 provides directionality to the transmission and reception of sound at the transducer 600, thereby reducing a sensitivity of the receiver 104 to extraneous noise. In one or more embodiments, a shape and dimensions of the throat 644 and the mouth 646 of the horn-shaped tuning port 601 can be determined in a manner similar to that discussed above in relation to the transmitter horn 240 and the receiver horn 242.

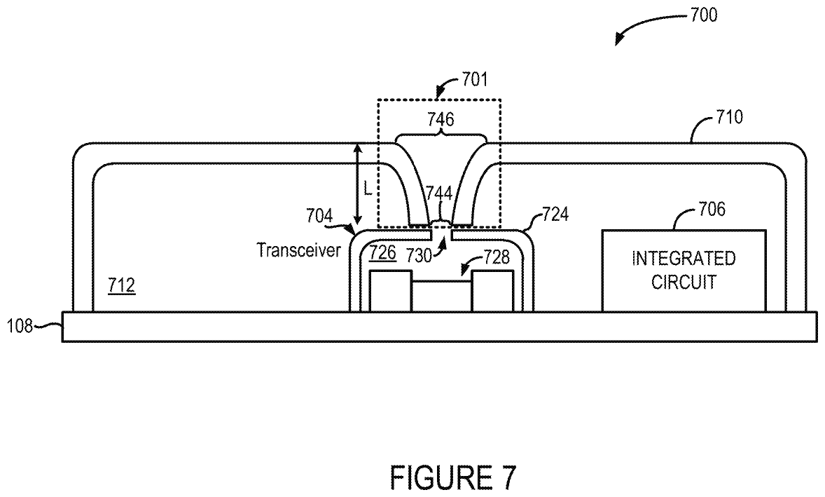

FIG. 7 illustrates an example of an embodiment of an ultrasonic transducer 700 which utilizes a horn shaped tuning port 701 and an ultrasonic transceiver 704 that can function as a receiver or a transmitter. The ultrasonic transducer 700 includes a housing 710 which is disposed on a substrate 108. The housing 710 defines a cavity 712 which encloses the transceiver 704 and an IC 706. The transceiver 704 includes a transceiver housing 724, which defines a cavity 726. The cavity 726 encloses a transducer 728, which is disposed over the substrate 108. The transceiver housing 724 defines an aperture, referred to as a transceiver port 730, on the surface of the housing 724 that faces the horn shaped tuning port 701. The horn-shaped tuning port 701 is similar to the tuning port 601 shown in FIG. 6, and includes a throat 744 and a mouth 746, which is coupled to the transducer housing 710. The horn-shaped turning port 701 is positioned in a manner such that the throat 744 is substantially aligned with the transceiver port 730. However, the throat 744 does not necessarily touch the surface of the transceiver housing 724. In one or more embodiments, the horn-shaped tuning port 701 can be positioned such that it makes contact with the surface of the transceiver housing 724 such that the opening of the throat 744 is aligned with the transceiver port 730, thereby isolating the transducer 728 from the cavity 712 defined by the transducer housing 710. In one or more embodiments, the horn-shaped tuning port 710 can be integrated with the transceiver 724 in a manner similar to that discussed above in relation to FIGS. 2A-3.

The dimensions of the horn-shaped tuning port 701 can be selected based on the operating frequency of the transceiver 704. In particular, a length L of the horn-shaped tuning port 701 can be selected such that a resonance frequency of the transducer housing 710 is substantially equal to an operating frequency f_{c} of the transceiver 704. For example, in one or more embodiments, the length L of the horn-shaped port 701 can be selected to be about ½ the wavelength of the operating frequency of the ultrasonic transducer 700. In one or more embodiments, a gap between the throat 744 and the transceiver housing 724 also can be selected to adjust the frequency characteristics of the transducer 700. The horn-shaped tuning port 701 provides strengthening of the sound energy in and out of the transducer 700, thereby improving a range of the transducer 700. In addition, the horn shape of the horn-shaped tuning port 701 provides directionality to the transmission and reception of sound at the transducer 700, thereby reducing a sensitivity of the transceiver 704 to extraneous noise. In one or more embodiments, a shape and dimensions of the throat 744 and the mouth 746 of the horn-shaped tuning port 701 can be determined in a manner similar to that discussed above in relation to the transmitter horn 240 and the receiver horn 242 shown in FIG. 2A.

The transceiver 704 can function as both a transmitter and as a receiver. For example, a MEMS microphone can be utilized to implement the transceiver 704, where the MEMS microphone, in conjunction with the IC 706 can operate as a transmitter for a first duration, and operate as a receiver for a second separate duration. Specifically, when operating as a transmitter, the transceiver 704 converts electrical signals received from the IC 706 into ultrasonic signals. When operating as a receiver, the transceiver 704 converts sensed ultrasonic signals into electrical signals, which are provided to the IC 706. In one or more embodiments, the first and second durations can be interspaced over time to allow the transceiver 704 to alternate between transmitting and receiving ultrasonic sound. A controller, such as the IC 706, can be configured to control the mode of the transceiver 704 (e.g., control when the transceiver 704 switches between operation as a transmitter and operation as a receiver).

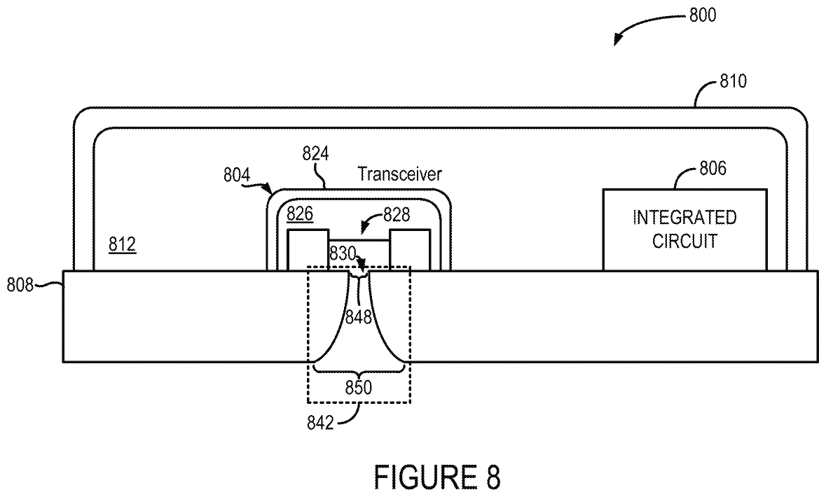

FIG. 8 illustrates an example of an embodiment of an ultrasonic transducer 800 incorporating horns in bottom ports of a transceiver 804. In particular, FIG. 8 shows that the ultrasonic transducer 800 incorporates a transceiver horn 842 within a substrate 808 over which the transceiver 804 is disposed. The transducer includes a transducer housing 810 that defines a cavity 812. The cavity 812 encloses the transceiver 804 and an IC 806. The transceiver 804 includes a transceiver housing 824, which defines a transceiver cavity 826 and encompasses a transducer 828. Similar to the transmitter horn 440 and the receiver horn 442 discussed above in relation to FIG. 4, the ultrasonic transducer 800 includes the transceiver horn 842 connected to a bottom port 830 of the transceiver 804. The transceiver horn 842 is formed in a horn-shaped channel within the substrate 808, and includes a throat 848 and a mouth 850, where the throat 848 is coupled to the bottom port 830 of the transceiver 804.

In one or more embodiments, such as the one shown in FIG. 8, the transceiver housing 824 and the transducer housing 810 do not include any openings. In one or more other embodiments, one or more of the above-mentioned housings can include ports. For example, the ports can be tuning ports that can be configured based on desired auditory responses of the ultrasonic transducer 800. In one or more embodiments, the substrate 808 can be a printed circuit board over which the ultrasonic transducer 800 is mounted. In other embodiments, the substrate 808 can be a semiconductor die over which the ultrasonic transducer is fabricated. In yet other embodiments, the substrate 808 can be a combination of a semiconductor die and a printed circuit board. One advantage of the ultrasonic transducer 800 with bottom port connected horns is that no additional material is needed to form the horns; instead, the existing substrate 808 can be utilized for forming the horns. The dimensions and the shape of the transceiver horn 842 can be determined in a manner similar to that discussed above in relation to the transmitter horn 240 and the receiver horn 242 shown in FIG. 2A. Further, various configurations of the throat and mouth of the horns shown in FIGS. 2C and 2D can be utilized for forming the throat 848 and the mouth 850 of the transceiver horn 842.

The transceiver 804 and the IC 806 can be similar to the transceiver 704 and the IC 706 discussed above in relation to FIG. 7. Particularly, the transceiver 804 can be configured by the IC 806 to operate as either a transmitter or a receiver, and can be alternated between transmitter/receiver operation as discussed with respect to the transceiver 704 and the IC 706.

The acoustic transducers discussed above in relation to FIGS. 2A-8 can be used in implementing a variety of proximity sensors and buttons. In one or more embodiments, these transducers can be used in implementing detection of proximity of objects to the transducer. For example, an ultrasonic transmitter (such as the transmitter 116 shown in FIG. 2A) or transceiver (such as the transceiver 704 shown in FIG. 7 operating as a transmitter) housed within the acoustic transducer housing transmits ultrasonic signals that exit the ultrasonic transducer housing through ports or openings. Receivers (such as the receiver 124 shown in FIG. 2A) or transceivers (such as the transceiver 704 shown in FIG. 7 operating as a receiver) sense a portion of the transmitted ultrasonic signals after being reflected from various objects located in the vicinity of the ultrasonic transducer. Changes in the distance of the surrounding objects from the ultrasonic transducer result in changes in one or more characteristics (such as signal strength, frequency, or phase) of the received ultrasonic signals. This change in the characteristics of the received ultrasonic signals can be measured to provide an indication of change of proximity of the objects from the ultrasonic transducer.

In one or more embodiments, the ultrasonic transducers discussed above in relation to FIGS. 2A-8 can be used in implementing buttons for receiving user input. For example, in one or more embodiments, the ultrasonic transducers can include a covering over one or more ports of the ultrasonic housing to serve as a button representation or button area, which a user can press to indicate a user input (e.g., an opening in the transducer housing 510 corresponding to the tuning port 501 can be fully or partially covered with a plate, which may include a button representation printed or inscribed on its surface). The plate can be formed of a material such as metal, plastic, rubber, or resin, or a combination of metal, plastic, rubber, and resin, or other material, the material providing a flexible surface that can deform in response to pressure applied by a user and can regain its form in the absence of the applied pressure. When a user presses on the plate, the plate bends. The bending of the plate, in turn, results in a change in one or more characteristics (such as signal strength, frequency, or phase) of signals transmitted by a transducer, reflected from the plate, and received by the transducer. This change in the characteristics of the received ultrasonic signals can be measured to identify a user input.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. An ultrasonic device comprising:
a substrate;
a transmitter disposed over the substrate, the transmitter comprising an ultrasonic transmitting transducer configured to generate ultrasonic signals;
a receiver disposed over the substrate, the receiver comprising an ultrasonic receiving transducer configured to sense ultrasonic signals; and
a first horn-shaped acoustic channel, wherein a material of at least one portion of the first horn-shaped acoustic channel is the same as a material of at least one portion of the transmitter or the receiver.

2. The device of claim 1, wherein the material of the at least one portion of the first horn-shaped acoustic channel is the same as a material of a portion of the transmitting transducer.

3. The device of claim 1, wherein the material of the at least one portion of the first horn-shaped acoustic channel is the same as a material of a portion of the receiving transducer.

4. The device of claim 1, wherein the first horn-shaped acoustic channel is integrated into the transmitter, further comprising a second horn-shaped acoustic channel integrated into the receiver.

5. The device of claim 4, wherein a material of at least one portion of the second acoustic channel is the same as a material of at least one portion of the receiver.

6. The device of claim 4, wherein the device is devoid of a bonding agent for bonding the first horn-shaped acoustic channel to the first transmitter and for bonding the second horn-shaped acoustic channel to the receiver.

7. The device of claim 4, wherein the transmitter comprises a transmitter housing defining a cavity, wherein a surface of the transmitter housing defines an aperture forming a first opening of the first horn-shaped acoustic channel, and the first opening of the first horn-shaped acoustic channel opens to the cavity.

8. The device of claim 4, wherein the receiver comprises a receiver housing defining a cavity, a surface of the receiving housing defines an aperture forming a first opening of the second horn-shaped acoustic channel, and the first opening of the second horn-shaped acoustic channel opens to the cavity.

9. The device of claim 4, further comprising a device housing disposed over the substrate and defining a third cavity, the transmitter and the receiver being within the third cavity, wherein a surface of the device housing defines a third aperture and a fourth aperture, and wherein the third aperture forms a second opening of the first horn-shaped acoustic channel, and wherein the fourth aperture forms a second opening of the second horn-shaped acoustic channel.

10. The device of claim 9, wherein an area of the first opening of the first horn-shaped acoustic channel is less than an area of the second opening of the first horn-shaped acoustic channel, and wherein an area of the first opening of the second horn-shaped acoustic channel is less than an area of the second opening of the second horn-shaped acoustic channel.

11. The device of claim 4, wherein the transmitting transducer comprises a MEMS transmitting transducer and wherein the receiving transducer comprises a MEMS receiving transducer.

12. An ultrasonic device comprising:
a substrate;
a transmitter disposed over the substrate, the transmitter comprising an ultrasonic transmitting transducer configured to generate ultrasonic signals;
a receiver disposed over the substrate, the receiver comprising an ultrasonic receiving transducer configured to sense ultrasonic signals;
a first housing disposed over the substrate defining a first cavity, the first cavity including the transmitter and the receiver, wherein a surface of the first housing defines a first aperture;
an acoustic channel having a first opening and an opposing second opening, the first opening coupled to the first aperture and the second opening coupled to the cavity, wherein a length of the acoustic channel is substantially equal to one half of an operating wavelength of the transmitter or the receiver.

13. The device of claim 12, wherein a diameter of the first opening of the acoustic channel is greater than a diameter of the second opening of the acoustic channel.

14. The device of claim 12, wherein the transmitter comprises a transmitter housing defining a second cavity, the second cavity encompassing the transmitting transducer, wherein the transmitter housing defines a second aperture, the second aperture forming an acoustic channel between the first cavity and the second cavity.

15. The device of claim 12, wherein the receiver comprises a receiver housing defining a second cavity, the second cavity encompassing the receiving transducer, wherein the receiver housing defines a second aperture, the second aperture forming an acoustic channel between the first cavity and the second cavity.

16. The device of claim 12, wherein the transmitting transducer comprises a MEMS transmitting transducer and wherein the receiving transducer comprises a MEMS receiving transducer.

17. An ultrasonic device comprising:
a substrate having a first planar surface and a second opposing planar surface;
a transmitter disposed over the first planar surface of the substrate;
a receiver disposed over the first planar surface of the substrate;
a first horn-shaped acoustic channel defined by the substrate, the first horn-shaped acoustic channel extending from a first opening defined in the first planar surface to a second opening defined in the second planar surface, wherein the first opening is proximate to the transmitting transducer; and
a second horn-shaped acoustic channel defined by the substrate, the second horn-shaped acoustic channel extending from a third opening defined in the first planar surface to a fourth opening defined in the second planar surface, wherein the third opening is proximate to the receiving transducer.

18. The device of claim 17, wherein an area of the first opening is less than an area of the second opening, and wherein an area of the third opening is less than an area of the fourth opening.

19. The device of claim 17, wherein the transmitter comprises a transmitter housing disposed over the first planar surface of the substrate, the transmitter housing defining a first cavity, and wherein the first cavity is coupled to the first horn-shaped acoustic channel via the first opening.

20. The device of claim 17, wherein the transmitting transducer comprises a MEMS transmitting transducer and wherein the receiving transducer comprises a MEMS receiving transducer.
